(19) United States
(12) Patent Application Publication
(10) Pub. No.: US 2007/0096786 A1
(43) Pub. Date: May 3, 2007

(54) RESET CIRCUIT

(75) Inventor: MING-CHIH HSIEH, Tu-Cheng,Taipei Hsien (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,760

(22) Filed: Sep. 22, 2006

(30) Foreign Application Priority Data
Oct. 28, 2005 (CN) 200510100807.3

(51) Int. Cl. H03K 3/02

(52) U.S. Cl. 327/198

(57) ABSTRACT

An exemplary reset circuit includes a reset signal generator and a control circuit. The reset signal generator provides a first reset signal. The control circuit includes a first reset signal input, a control terminal, and an output. The first reset signal input receives the first reset signal, the control terminal receives a control signal, and the control circuit delivers a second reset signal at the output in response to the first reset signal and the control signal. The reset signal generator associated with the control circuit protects a system from accidental reset.

### FIELD OF THE INVENTION

The present invention relates to a reset circuit, and particularly to an improved reset circuit having a control circuit for protecting a computer system from an undesired reset.

### DESCRIPTION OF RELATED ART

Reset circuits for resetting the state of a circuit system to an original state, and the operation of a conventional reset circuit, are illustrated in FIG. 2. Referring to FIG. 2, the conventional reset circuit comprises a resistor R′, a diode D′, a capacitor C′, and a reset button S′. The resistor R′ and the reset button S′ are connected between a power supply Vcc and the ground in series. The diode D′ and the capacitor C′ are connected between the power supply Vcc and the ground in series with a cathode of the diode D′ connected to the power supply Vcc and an anode of the diode D′ connected to the capacitor C′. A node between the diode D′ and the capacitor C′ is connected to a node between the resistor R′ and the reset button S′. The node between the resistor R′ and the reset button S′ acts as a reset signal output terminal A′. When the reset button S′ is not pressed down, the voltage at the output terminal A′ is at a high level, and the system works normally. When the reset button S′ is pressed down, the voltage at the output terminal A′ goes to a low level, and a reset signal is output from the power circuit for resetting the system. However, if the reset button is inadvertently pressed, an undesired reset of the system occurs, and the system may experience data damage, data loss, file corruption, or hardware damage. It is apparent that the system does not provide adequate protection against such occurrences.

What is needed is to provide an improved reset circuit which provides adequate protection against accidental reset.

### SUMMARY OF THE INVENTION

An exemplary reset circuit includes a reset signal generator and a control circuit. The reset signal generator provides a first reset signal. The control circuit includes a first reset signal input, a control terminal, and an output. The first reset signal input receives the first reset signal, the control terminal receives a control signal, and the control circuit delivers a second reset signal at the output in response to the first reset signal and the control signal.

Other advantages and novel features of the invention will become more apparent from the following detailed description when taken in conjunction with the accompanying drawings, in which:

### BRIEF DESCRIPTION OF THE DRAWINGS

FIG. 1 is a circuit diagram of a reset circuit in accordance with a preferred embodiment of the present invention; and

FIG. 2 is a circuit diagram of a conventional reset circuit.

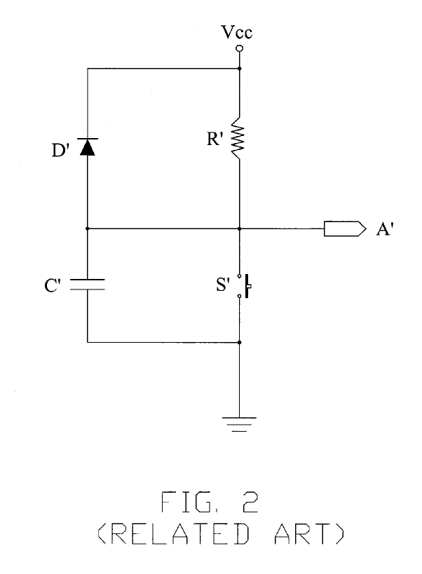

### DETAILED DESCRIPTION OF THE INVENTION

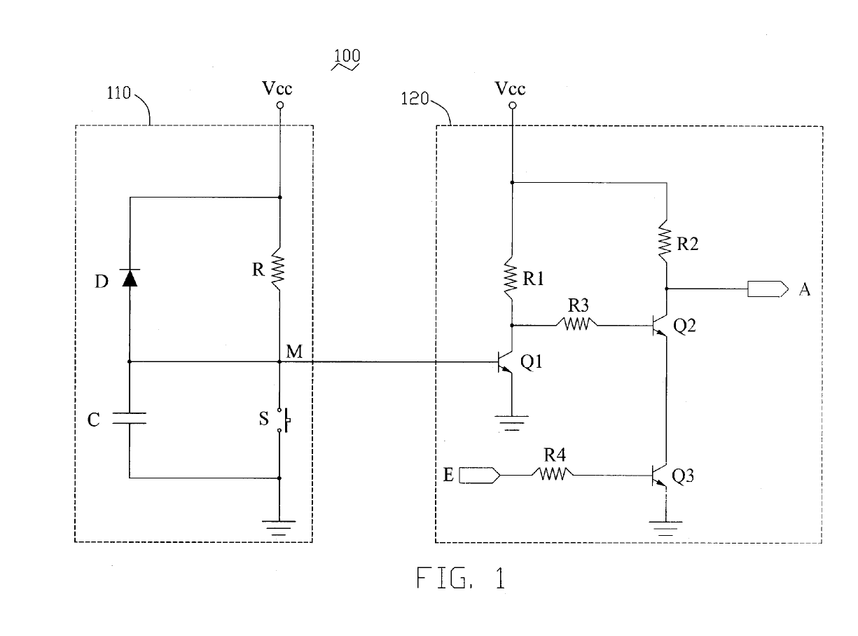

Referring to FIG. 1, a reset circuit 100 in accordance with a preferred embodiment of the present invention includes a reset signal generator 110 and a control circuit 120.

The reset signal generator 110 comprises a resistor R, a diode D, a capacitor C, and a reset button S. The resistor R and the reset button S are connected between a power supply Vcc and ground in series. The diode D and the capacitor C are connected between the power supply Vcc and ground in series with a cathode of the diode D connected to the power supply Vcc and an anode of the diode D connected to the capacitor C. A node between the diode D and the capacitor C is connected to a node M between the resistor R and the reset button S. The node M acts as a first reset signal output terminal.

The control circuit 120 includes a plurality of transistors Q1˜Q3, and a plurality of resistors R1˜R4. A base of the first transistor Q1 acts as a first reset signal input of the control circuit 120 and is connected to the node M, a collector of the first transistor Q1 is connected to the power supply Vcc via the resistor R1, and an emitter of the first transistor Q1 is grounded. A base of the second transistor Q2 is connected to the collector of the first transistor Q1 via the resistor R3. A collector of the second transistor Q2 is connected to the power supply Vcc via the resistor R2, and an emitter of the second transistor Q2 is connected to a collector of the third transistor Q3. A base of the third transistor Q3 is connected to a control terminal E via the resistor R4, and an emitter of the third transistor Q3 is grounded. The node between the resistor R2 and the collector of the second transistor Q2 acts as an output A of the control circuit 120.

In operation, if a system utilizing the reset circuit 100 need not be reset, a voltage at the control terminal E is set at a low level by a user command at a terminal of the system, the third transistor Q3 is turned off, and the second transistor Q2 is also turned off, a voltage at the output A of the control circuit 120 is always high, and the system can not be reset, even if the reset button S is pushed.

If the system needs to be reset, the voltage at the control terminal E is set at a high level, the third transistor Q3 is turned on. If the reset button S is not pressed down, the voltage at the node M is at a high level, the first transistor Q1 is turned on, the second transistor Q2 is turned off, the voltage at the output A of the control circuit 120 is high, and the system works normally. If the reset button S is pressed down, the first reset signal is at a low level, the voltage at the base of the first transistor Q1 is at a low level, the first transistor Q1 is turned off, the second transistor Q2 is turned on, the transistor Q3 is turned on, so the voltage at the output A of the control circuit 120 is at a low level, and a second reset signal is output from the output A of the control circuit 120 for resetting the system.

According to the above embodiment, an enable control signal is output from the control terminal E of the control circuit 120 when the system is to be reset, and the reset signal generator 110 outputs a first reset signal to the control circuit 120, a second reset signal is output from the control circuit 120 for resetting the system in accordance with the first reset signal and the control signal. When the system need not be reset, the control signal at the control circuit is disabled, the system cannot be reset even if the first reset signal is received. So the reset signal generator 110 associated with the control circuit 120 protects the system from an accidental reset.

It is believed that the present embodiment and its advantages will be understood from the foregoing description, and it will be apparent that various changes may be made thereto without departing from the spirit and scope of the invention or sacrificing all of its material advantages, the example hereinbefore described merely being preferred or exemplary embodiment of the invention.

What is claimed is:

1. A reset circuit, comprising:
a reset signal generator providing a first reset signal; and
a control circuit comprising a first reset signal input receiving the first reset signal, a control terminal receiving a control signal, and an output, the control circuit delivering a second reset signal to a system at the output in response to the first reset signal and the control signal, when the first reset signal and the control signal are enabled, the system is reset.

2. The reset circuit as claimed in claim 1, wherein the reset signal generator comprises a resistor, a diode, a capacitor, and a reset button, the resistor and the reset button are connected between a power supply and ground in series, the diode and the capacitor are connected between the power supply and ground in series with a cathode of the diode connected to the power supply and an anode of the diode connected to the capacitor, a node between the diode and the capacitor is connected to a node between the resistor and the reset button.

3. The reset circuit as claimed in claim 2, wherein the control circuit comprises a first resistor, a second resistor, a third resistor, a first transistor, a second transistor, and a third transistor, a base of the first transistor acts as the first reset signal input, a collector of the first transistor is connected to a power supply via the first resistor, an emitter of the first transistor is grounded, a base of the second transistor is connected to the collector of the first transistor via the second resistor, a collector of the second transistor is connected to the power supply via a third resistor, an emitter of the second transistor is connected to a collector of the third transistor, a base of the third transistor is connected to the control terminal via the fourth transistor, an emitter of the third transistor is grounded, and a node between the third resistor and the collector of the second transistor acts as the output of the control circuit.

4. A reset circuit, comprising:
a first transistor comprising a base receiving a first reset signal, a collector connected to a power supply, and an emitter being grounded;
a second transistor comprising a base connected to the collector of the first transistor via a first resistor, a collector connected to the power supply and acting as an output of the reset circuit, and an emitter; and
a third transistor comprising a base receiving a control signal, a collector connected to the emitter of the second transistor, and an emitter being grounded.

5. The reset circuit as claimed in claim 4, wherein a second resistor is connected between the collector of the first transistor and the power supply.

6. The reset circuit as claimed in claim 5, wherein a third resistor is connected between the collector of the second transistor and the power supply.

7. A reset circuit, comprising:
a reset signal generator providing a first reset signal; and
a control circuit comprising a first reset signal input receiving the first reset signal, a control terminal receiving a control signal, and an output configured for outputting a second reset signal to a system in response to the first reset signal and the control signal, wherein when the control signal is enabled, the second reset signal is capable of resetting the system in accordance with the first reset signal, and
when the control signal is disenabled, the second reset signal is not capable of resetting the system.

8. The reset circuit as claimed in claim 7, wherein the control circuit comprises a first transistor having a base configured for receiving the first reset signal, a second transistor having a connector configured for outputting the second reset signal, and a third transistor having a base configured for receiving the control signal, a connector of the first transistor electrically coupling to a base of the second transistor, a connector of the third transistor electrically coupling to an emitter of the second transistor.
